(19) United States
(12) Patent Application Publication
(10) Pub. No.: US 2026/0088610 A1
(43) Pub. Date: Mar. 26, 2026

(54) INPUT/OUTPUT (I/O) CIRCUIT COMPATIBLE FOR VERTICAL AND HORIZONTAL PLACEMENT

(71) Applicant: QUALCOMM Incorporated, San Diego, CA (US)

(72) Inventors: Roshan Kumar SHARMA, Bangalore (IN); Roshan Thonse SHETTY, Bangalore (IN); Deepa SRIRAM, Bangalore (IN); Sumit Sudhakarrao BIRADAR, Bengaluru (IN)

(21) Appl. No.: 18/808,855

(22) Filed: Aug. 19, 2024

(51) Int. Cl. H02H 9/04

(52) U.S. Cl. CPC H02H 9/046

(57) ABSTRACT

An integrated circuit, including: a sealring; a core region; and a first input/output (I/O) cell, comprising: a first diagonal signal routing cell; and a first electrostatic discharge (ESD) protection cell stacked with the first diagonal signal routing cell between the sealring and the core region, wherein the first diagonal signal routing cell is configured to route a first outbound signal from a first pin located substantially at a first corner of the first diagonal signal routing cell adjacent to the core region to a second pin located substantially at a second corner of the first diagonal signal routing cell adjacent to the first ESD protection cell.

### FIELD

This disclosure relates generally to input/output (I/O) circuits, and in particular, to an I/O circuit compatible for vertical and horizontal placement along north/south and east/west periphery of an integrated circuit (IC), such as a system on chip (SOC).

### BACKGROUND

An integrated circuit (IC), such as a system on chip (SOC), (hereinafter “chip”) typically includes linear arrays of input/output (I/O) circuits or cells to signal interface core circuitry to components external to the chip. As chips are typically square or rectangular in shape, I/O cells are typically arrayed along the four peripheral sides of the chip surrounding a core region. In the past, I/O cells along the north-south periphery of the chip have been layout differently than I/O circuits or cells along the east-west periphery of the chip due to various foundry requirements (e.g., polysilicon extending in the same direction throughout the chip, latchup injectors not located on the core side of the I/O cells). This has the undesirable consequence of requiring substantial efforts in the design of I/O cells.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an integrated circuit. The integrated circuit includes: a sealring; a core region; and a first input/output (I/O) cell, comprising: a first diagonal signal routing cell; and a first electrostatic discharge (ESD) protection cell stacked with the first diagonal signal routing cell between the sealring and the core region, wherein the first diagonal signal routing cell is configured to route a first outbound signal from a first pin located substantially at a first corner of the first diagonal signal routing adjacent to the core region to a second pin located substantially at a second corner of the first diagonal signal routing cell adjacent to the first ESD protection cell.

Another aspect of the disclosure relates to an integrated circuit. The integrated circuit includes: a square or rectangular shaped sealring including a north side, an east side, a south side, and a west side; a core region situated within the sealring; a first linear array of vertical input/output (I/O) cells extending parallel with the north side of the sealring, and situated between the north side of the sealring and the core region, wherein each of the vertical I/O cells of the first linear array includes a first electrostatic discharge (ESD) protection cell stacked with a first diagonal signal routing cell in a north-to-south vertical direction, respectively; a second linear array of vertical I/O cells extending parallel with the south side of the sealring, and situated between the south side of the sealring and the core region, wherein each of the vertical I/O cells of the second linear array includes a second ESD protection cell stacked with a second diagonal signal routing cell in a south-to-north vertical direction, respectively; a first linear array of horizontal I/O cells extending parallel with the east side of the sealring, and situated between the east side of the sealring and the core region, wherein each of the horizontal I/O cells of the first linear array includes a third ESD protection cell stacked with a third diagonal signal routing cell in an east-to-west horizontal direction, respectively; and a second linear array of horizontal I/O cells extending parallel with the west side of the sealring, and situated between the west side of the sealring and the core region, wherein each of the horizontal I/O cells of the second linear array includes a fourth ESD protection cell stacked with a fourth diagonal signal routing cell in a west-to-east horizontal direction, respectively.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example input/output (I/O) circuit in accordance with an aspect of the disclosure.

FIG. 2 illustrates a floorplan view of an example integrated circuit (IC), such as a system on chip (SOC), in accordance with another aspect of the disclosure.

FIGS. 3A-3B illustrate floorplan views of example vertical and horizontal I/O circuits or cells in accordance with another aspect of the disclosure.

FIG. 4 illustrates a floorplan view of another example integrated circuit (IC), such as a system on chip (SOC), in accordance with another aspect of the disclosure.

FIGS. 5A-5B illustrate floorplan views of example vertical and horizontal I/O circuits or cells in accordance with another aspect of the disclosure.

FIG. 6 illustrates a floorplan view of another example integrated circuit (IC), such as a system on chip (SOC), in accordance with another aspect of the disclosure.

FIGS. 7A-7B illustrate floorplan views of example vertical and horizontal I/O circuits or cells in accordance with another aspect of the disclosure.

FIGS. 8A-8B illustrate floorplan views of example vertical and horizontal I/O circuits or cells in accordance with another aspect of the disclosure.

FIGS. 9A-9B illustrate floorplan views of example vertical and horizontal I/O circuits or cells in accordance with another aspect of the disclosure.

FIG. 10 illustrates a floor plan view of a set of metal traces including selectable core pins for electrical coupling vertical and horizontal I/O circuits or cells to core circuits in accordance with another aspect of the disclosure.

FIG. 11A illustrates a floorplan view of an example set of upper metal traces associated with a vertical I/O circuit or cell in accordance with another aspect of the disclosure.

FIG. 11B illustrates a floorplan view of an example set of upper metal traces associated with a horizontal I/O circuit or cell in accordance with another aspect of the disclosure.

FIG. 11C illustrates a floorplan view of an example parasitic equalizing shield for both vertical and horizontal I/O circuits or cells in accordance with another aspect of the disclosure.

FIG. 11D illustrates a side cross sectional view of an example portion of an integrated circuit, such as a system on chip (SOC), in accordance with another aspect of the disclosure.

FIG. 11E illustrates a side cross sectional view of an example portion of an integrated circuit, such as a system on chip (SOC), in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances or practical layout placement.

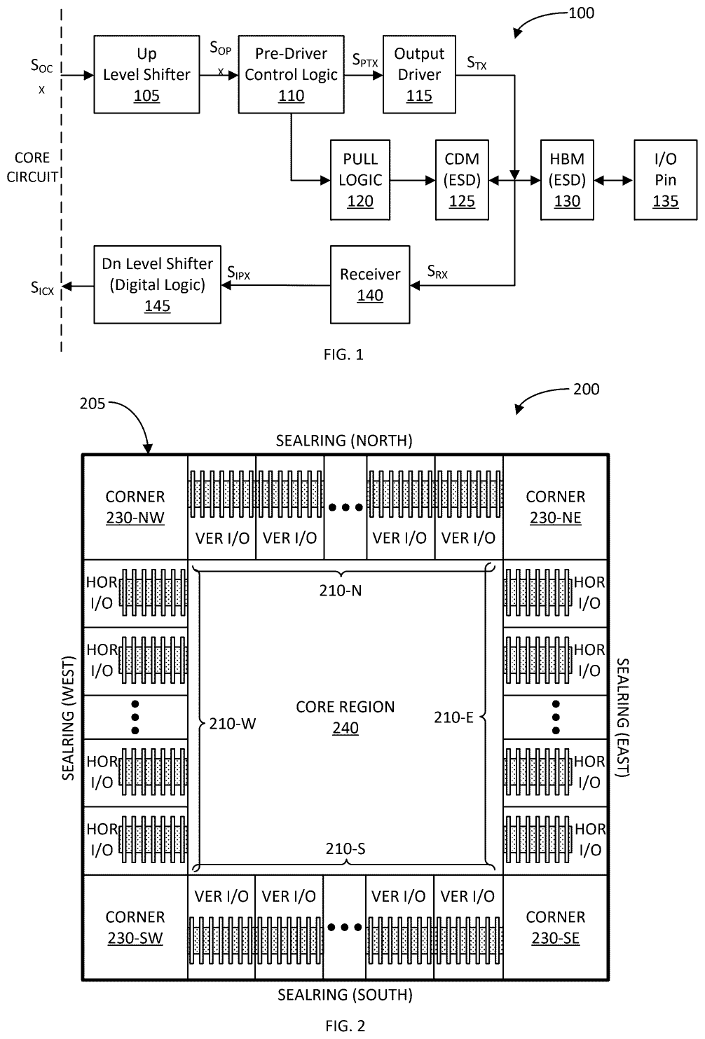

FIG. 1 illustrates a block diagram of an example input/output (I/O) circuit 100 in accordance with an aspect of the disclosure. The I/O circuit 100 may be implemented in an integrated circuit (IC), such as a system on chip (SOC), (referred to hereinafter as a “chip”). As discussed in more detail further herein, an array of the I/O circuits 100 are placed around an internal periphery of a chip, just inside of a sealring, and between a core region and an array of I/O pins, respectively. Each I/O circuit 100 is configured to provide a signal interface between a core circuit and an I/O pin.

In particular, the I/O circuit 100 includes an up level shifter 105, a pre-driver with control logic 110, an output driver 115, a pull (e.g., up and/or down) logic circuit 120, a charge device model (CDM) electrostatic discharge (ESD) protection circuit 125, a human body model (HBM) ESD protection circuit 130, an I/O pin 135, a receiver 140, and a down level shifter (including digital logic) 145.

With regard to signal transmission, the up level shifter 105 is configured to up-voltage level shift an outbound data signal S_{OCX} in a core voltage domain received from a core circuit to generate an outbound data signal S_{OPX} in a I/O voltage domain suitable for transmission external to the chip. The pre-driver with control logic 110 includes one or more cascaded pre-drivers configured to generate a pre-transmit data signal S_{PTX} based on the outbound data signal S_{OPX}. The output driver 115 is configured to generate a transmit data signal S_{TX} based on the pre-transmit data signal S_{PTX}. The transmit data signal S_{TX} is routed to the I/O pin 135 via the HBM ESD protection circuit 130 for external transmission outside of the chip.

With regard to signal reception, the receiver 140 is configured to receive a data signal S_{RX} from the I/O pin 135 of the chip via the HBM ESD protection circuit 130. The receiver 140 is configured to process the received data signal S_{RX} (e.g., amplify, equalize, data detect, etc.) to generate an inbound data signal S_{IPX} in the I/O voltage domain. The down level shifter (with digital logic) 145 is configured to down-voltage level shift and process the received data signal S_{IPX} to generate an inbound data signal S_{ICX} in the core voltage domain. The inbound data signal S_{ICX} is provided to the core circuit for further processing.

The pull logic circuit 120 is configured to pull-up and/or pull-down the voltage at the I/O pin 135 in response to the control logic of the pre-driver 110 determining that the I/O circuit 100 is disabled. This prevents the floating of the I/O pin 135, where an unknown voltage/noise may otherwise develop and trigger unintended operations in the I/O circuit 100. The HBM and CDM ESD protection circuits 130 and 125 provide ESD protection for the I/O circuit 100.

FIG. 2 illustrates a floorplan (layout) view of an example integrated circuit (IC) 200, such as a system on chip (SOC), (e.g., referred to hereinafter as a “chip”) in accordance with another aspect of the disclosure. The chip 200 includes a sealring 205 defining a boundary or periphery inside of which circuits or cells of the chip 200 are situated. As the chip 200 may be square or rectangular in shape, the sealring 205 likewise includes four sides designated as north, east, south, and west, respectively. A vertical direction, as defined herein, extends between the north and south sides of the sealring 205 parallel with the east and west sides of the sealring 205. A horizontal direction, as defined herein, extends between the east and west sides of the sealring 205 parallel with the north and south sides of the sealring 205. A cell, as defined herein, is a functional circuit organized into a prescribed area or block (e.g., a square block, a rectangular block, an L-shaped block, etc.) of an IC chip.

The chip 200 includes a first linear array of vertical I/O circuits or cells 210-N extending horizontally along the north side of the sealring 205 between corner cells 230-NW and 230-NE, respectively. The first linear array of vertical I/O circuits or cells 210-N are situated between the north side of the sealring 205 and a core region 240 (e.g., where core circuits are situated) at a central region of the chip 200. The chip 200 further includes a second linear array of vertical I/O circuits or cells 210-S extending horizontally along the south side of the sealring 205 between corner cells 230-SW and 230-SE, respectively. The second linear array of vertical I/O circuits or cells 210-S are situated between the south side of the sealring 205 and the core region 240. The cell layout of each of the vertical I/O cells of the second linear array 210-S is the same as the cell layout of each of the vertical I/O cells of the first linear array 210-N, but rotated 180 degrees with respect to each other.

Additionally, the chip 200 includes a first linear array of horizontal I/O circuits or cells 210-E extending vertically along the east side of the sealring 205 between corner cells 230-NE and 230-SE, respectively. The first linear array of horizontal I/O circuits or cells 210-N are situated between the east side of the sealring 205 and the core region 240 of the chip 200. The chip 200 further includes a second linear array of horizontal I/O circuits or cells 210-W extending vertically along the west side of the sealring 205 between corner cells 230-NW and 230-SW, respectively. The second linear array of horizontal I/O circuits or cells 210-W are situated between the west side of the sealring 205 and the core region 240 of the chip 200. Similarly, the cell layout of each of the horizontal I/O cells of the second linear array 210-W is the same as the cell layout of each of the horizontal I/O cells of the first linear array 210-E, but rotated 180 degrees with respect to each other.

Foundries of IC chips typically require that the polysilicon (or “poly” for short) (e.g., gate electrodes of field effect transistors (FETs)) are elongated or extend along the same direction throughout a chip, such as, vertically in the example chip 200. Based on such requirement, the poly in the vertical I/O cells 210-N/210-S extend vertically in the direction from north/south sides of the sealring 205 towards the core region 240 of the chip 200, respectively. Whereas, in the horizontal I/O cells 210-E/210-W, the poly still extends vertically, but not in the direction from the corresponding east/west sides of the sealring 205 towards the core region 240. As a consequence, the horizontal I/O cells 210-E/210-W require a different layout design than the vertical I/O cells 210-N/210-S. This dual design effort for vertical and horizontal I/O cells adds significant time to the development of I/O cells including design, layout, post-layout tweaks, functional, timing, and quality assistance (QA) verification, etc.

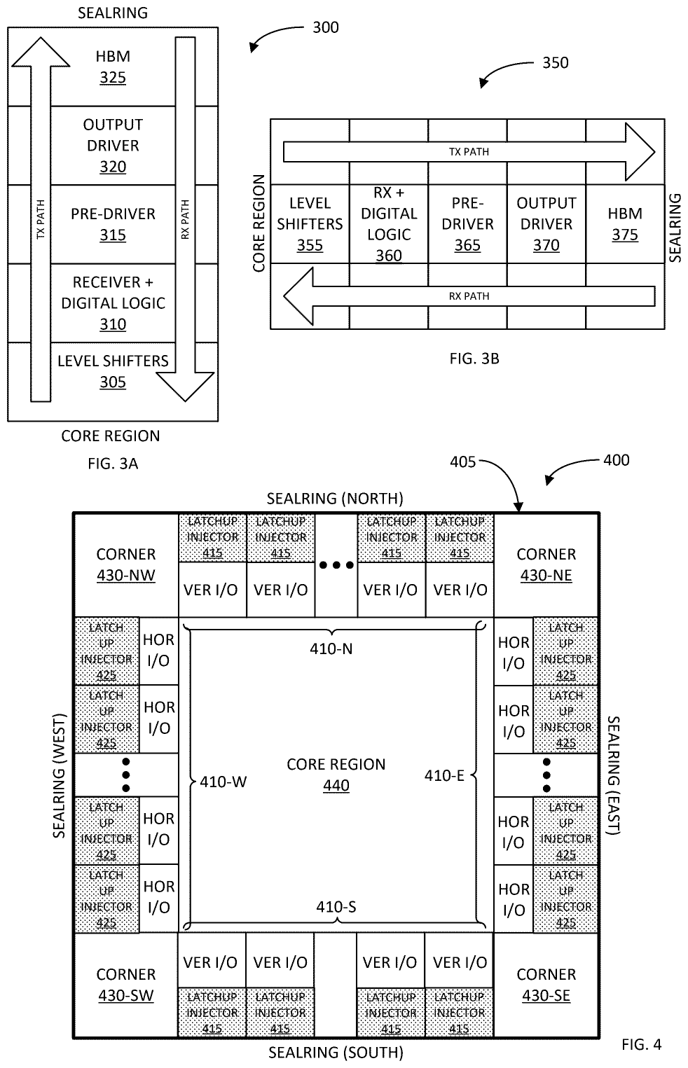

FIG. 3A illustrates a floorplan (layout) view of an example vertical I/O circuit or cell 300 in accordance with another aspect of the disclosure. The vertical I/O cell 300 includes level shifters cell 305 (e.g., up and down), a receiver plus digital logic cell 310, a pre-driver cell 315, an output driver cell 320, and an HBM ESD protection cell 325 stacked in the vertical direction between a sealring and core region of a chip. In this configuration, a transmit (Tx) path is shown to extend from the core region towards the sealring side of a chip via the level shifters cell 305, the receiver plus digital logic cell 310, the pre-driver cell 315, the output driver cell 320, and the HBM ESD protection cell 325. Similarly, a receive (Rx) path is shown to extend from the sealring side to the core region of the chip via the HBM ESD protection cell 325, the output driver cell 320, the pre-driver cell 315, the receiver plus digital logic cell 310, and the level shifters cell 305.

FIG. 3B illustrates a floorplan (layout) view of an example horizontal I/O circuit or cell 350 in accordance with another aspect of the disclosure. The horizontal I/O cell 350 includes level shifters cell 355 (e.g., up and down), a receiver plus digital logic cell 360, a pre-driver cell 365, an output driver cell 370, and an HBM ESD protection cell 375 stacked in the horizontal direction between the sealring and the core region of a chip. In this configuration, a transmit (Tx) path is shown to extend from the core region towards the sealring of a chip via the level shifters cell 355, the receiver plus digital logic cell 360, the pre-driver cell 365, the output driver cell 370, and the HBM ESD protection cell 375. Similarly, a receive (Rx) path is shown to extend from the sealring side to the core region of the chip via the HBM ESD protection cell 375, the output driver cell 370, the pre-driver cell 365, the receiver plus digital logic cell 360, and the level shifters cell 355.

FIG. 4 illustrates a floorplan (layout) view of another example integrated circuit (IC) 400, such as a system on chip (SOC), (e.g., hereinafter “chip”) in accordance with another aspect of the disclosure. The chip 400 includes a first linear array of vertical I/O circuits or cells 410-N extending horizontally along the north side of a sealring 405 between corner cells 430-NW and 430-NE, respectively. The first linear array of vertical I/O circuits or cells 410-N are situated between the north side of the sealring 405 and a core region 440 (e.g., where core circuits are situated) at a central region of the chip 400. The chip 400 further includes a second linear array of vertical I/O circuits or cells 410-S extending horizontally along the south side of the sealring 405 between corner cells 430-SW and 430-SE, respectively. The second linear array of vertical I/O circuits or cells 410-S are situated between the south side of the sealring 405 and the core region 440. The cell layout of each of the vertical I/O cells of the second linear array 410-S is the same as the cell layout of each of the vertical I/O cells of the first linear array 410-N, but rotated 180 degrees with respect to each other. Further, each of the vertical I/O cells 410-N/410-S includes a latchup injector 415 situated on the sealring side of the cell.

Additionally, the chip 400 includes a first linear array of horizontal I/O circuits or cells 410-E extending vertically along the east side of the sealring 405 between corner cells 430-NE and 430-SE, respectively. The first linear array of horizontal I/O circuits or cells 410-N are situated between the east side of the sealring 405 and the core region 440 of the chip 400. The chip 400 further includes a second linear array of horizontal I/O circuits or cells 410-W extending vertically along the west side of the sealring 405 between corner cells 430-NW and 430-SW, respectively. The second linear array of horizontal I/O circuits or cells 410-W are situated between the west side of the sealring 405 and the core region 440 of the chip 400. The cell layout of each of the horizontal I/O cells of the second linear array 410-W is the same as the cell layout of each of the horizontal I/O cells of the first linear array 410-E, but rotated 180 degrees with respect to each other. Each of the horizontal I/O cells 410-E/410-W includes a latchup injector 425 situated on the sealring side of the cell.

Another requirement that may be imposed by some foundries of IC chips dictates that latchup injectors 415 and 425 not lie on the core side of each of the vertical and horizontal I/O cells 410-N/410-S and 410-E/410-W, respectively. A latchup injector may include the output driver cell 320/370 and the HBM ESD protection cell 325/375, which may be a source of latchup for core circuits if placed on the core side of each of the vertical and horizontal I/O cells 410-N/410-S and 410-E/410-W. Latchup is an overcurrent produced in complementary metal oxide semiconductor (CMOS) field effect transistors (FETs) due to parasitic pn junctions present in CMOS FETs. Large devices, such as output drivers 320/370 and HBM ESD protection circuits 325/375, may be sources or injectors for latchup in core circuits if placed near or adjacent to the core region 440 of the chip 400.

Thus, another reason that the vertical and horizontal I/O cells 410-N/410-S and 410-E/410-W need to have different layout configuration is due to the requirement for latchup injectors 415 and 425 being placed on the sealring side of the vertical and horizontal I/O cells 410-N/410-S and 410-E/410-W. For instance, one of the vertical I/O cell 410-N may not be “dragged and dropped” as one of the horizontal I/O cell 410-W because its latchup injector 415 would lie next to the core region 440 of the chip. Similarly, one of the horizontal I/O cell 410-E may not be “dragged and dropped” as a vertical I/O cell 410-S because its latchup injector 425 would lie next to the core region 440 of the chip. Thus, there is a need for an I/O cell which may be used for both vertical and horizontal orientation placement while maintaining the requirements of the poly being in the same direction and latchup injectors lying on the sealring side of the cell.

FIG. 5A illustrates a floorplan (layout) view of an example vertical I/O cell or circuit 500 in accordance with another aspect of the disclosure. The vertical I/O cell 500 includes a vertical HBM ESD protection cell 510 (e.g., HBM_VER) stacked in a substantially vertically aligned manner with a diagonal signal routing cell 520 between a sealring and a core region of a chip. The diagonal signal routing cell 520 includes a set of cells 522, 524, and 526 configured to route an outbound signal from proximate one corner (e.g., the bottom-left corner adjacent to the core region) to proximate an opposite corner (e.g., the top-right corner adjacent to the vertical HBM ESD protection cell 510) of the diagonal signal routing cell 520. It shall be understood that the diagonal signal routing cell 520 may route an outbound signal between the other opposite corners (e.g., from bottom-right corner to top-left corner).

The cell 522 may be implemented as an L-shaped cell including a first leg that extends in the vertical direction between the vertical HBM ESD protection cell 510 and a lower (e.g., core region) boundary of the vertical I/O cell 500, and a second leg that extends in the horizontal direction, parallel with and next to the core region, across the width or horizontal (e.g., left and right) boundaries of the vertical I/O cell 500. Similarly, the cell 526 may also be implemented as an L-shaped cell including a first leg that extends in the horizontal direction between the first leg of the L-shaped cell 522 and a horizontal (e.g., right) boundary of the vertical I/O cell 500, and a second leg that extends between the vertical HBM ESD protection cell 510 and the second leg of the L-shaped cell 522. The cell 524, which may be square or rectangular in shape, may be sandwiched between respective portions of the first and second legs of the L-shaped cells 526 and 522 in the vertical direction, and sandwiched between respective portions of the first and second legs of the L-shaped cells 522 and 526 in the horizontal direction.

The cell 522 may include a pair of selectable input pins 530 and 532 situated substantially at the bottom-left corner of the diagonal signal routing cell 520 (e.g., proximate the intersection of the first and second legs of the L-shaped cell 522). Similarly, the cell 526 may include a pair of selectable output pins 534 and 536 situated substantially at a top-right corner of the diagonal signal routing cell 520 (e.g., proximate the intersection of the first and second legs of the L-shaped cell 526). In the case of the vertical I/O cell 500, the selected one of the selectable input pins 530 and 532 may be the input pin 532 (as indicated with a dark shading) for coupling to a core circuit (as it is closer to the core region than the unselected input pin 530). The unselected input pin 530 is depicted with no shading. Also, in the case of the vertical I/O cell 500, the selected one of the selectable output pins 534 and 536 may be the output pin 534 (as indicated with a dark shading) for coupling to the vertical HBM ESD protection cell 510 (as it is closer to the vertical HBM ESD protection cell 510 than the unselected output pin 536). The unselected output pin 536 is indicated with no shading.

The cells 522, 524, and 526 are configured to route an outbound signal from the selected input pin 532 to the selected output pin 534 diagonally across the diagonal signal routing cell 520, as indicated by the dashed arrow line. The signal routing path being diagonal may include a series of horizontal and vertical routing paths that collectively approximate the diagonal signal routing path. The vertical I/O cell 500 is configured to receive the outbound signal from a core circuit via the selected input pin 532 as indicated by the solid dark arrow line extending from the core region to the selected input pin. The dashed arrow line pointing to the unselected input pin 530 is depicted with no shading to indicate that in the vertical I/O cell use of the diagonal signal routing cell 520 no outbound signal is received via the unselected input pin 530. The diagonal signal routing cell 520 is configured to provide the outbound signal to the vertical HBM ESD protection cell 510 via the selected output pin 534 as indicated by the solid dark arrow line extending from the diagonal signal routing cell 520 to the vertical HBM ESD protection cell 510. The dashed arrow line pointing from the unselected output pin 536 is depicted with no shading to indicate that in the vertical I/O cell use of the diagonal signal routing cell 520 no outbound signal is transmitted via the unselected output pin 536. The outbound signal may collectively include the data signals S_{OCX}, S_{OPX}, S_{PTX}, and S_{TX} as described with reference to I/O circuit 100.

As discussed further with reference to a more detailed implementation of the vertical I/O cell 500, the cell 526 may include an output driver of the vertical I/O cell 500. In this manner, the latchup injectors of the vertical I/O cell 500, namely the vertical HBM ESD protection cell 510 and the output driver cell 526, are not situated next to the core region of the chip. For example, the vertical HBM ESD protection cell 510 and the output driver cell 526 are separated from the core region by the cell 522 to prevent latchup in the core circuits as previously discussed. The cell 522, as it is situated next to the core region, may include I/O circuitry other than the latchup injectors 510/526, such as level shifters, digital logic, pull logic, CDM ESD protection circuit, and receiver. The intermediate cell 524 may include a pre-driver and control logic as it is situated between the level shifters and output driver from a signal flow perspective.

FIG. 5B illustrates a top view of an example horizontal I/O cell or circuit 550 in accordance with another aspect of the disclosure. The horizontal I/O cell 550 includes a horizontal HBM ESD protection cell 560 (e.g., HBM_HOR) stacked in a substantially horizontal aligned manner with the diagonal signal routing cell 520 between a sealring and a core region of a chip. Note that the horizontal I/O cell 550 uses the same (layout wise) diagonal signal routing cell 520 to route an outbound signal diagonally from a core circuit to the horizontal HBM ESD protection cell 560.

In the case of the horizontal I/O cell 550, the selected one of the selectable input pins 530 and 532 may be the input pin 530 (as indicated with a dark shading) for coupling to a core circuit (as it is closer to the core region than the unselected input pin 532). The unselected input pin 532 is depicted with no shading. Also, in the case of the horizontal I/O cell 550, the selected one of the selectable output pins 534 and 536 may be the output pin 536 (as indicated with a dark shading) for coupling to the horizontal HBM ESD protection cell 560 (as it is closer to the horizontal HBM ESD protection cell 560 than the unselected output pin 534). The unselected output pin 534 is depicted with no shading.

Similarly, the cells 522, 524, and 526 are configured to route an outbound signal from the selected input pin 530 to the selected output pin 536 diagonally across the diagonal signal routing cell 520, as indicated by the dashed arrow line. The horizontal I/O cell 550 is configured to receive the outbound signal from a core circuit via the selected input pin 530 as indicated by the solid dark arrow line extending from the core region to the selected input pin. The dashed arrow line pointing to the unselected input pin 532 is depicted with no shading to indicate that in the horizontal I/O cell use of the diagonal signal routing cell 520 no outbound signal is received via the unselected input pin 532. The diagonal signal routing cell 520 is configured to provide the outbound signal to the horizontal HBM ESD protection cell 560 via the selected output pin 536 as indicated by the solid dark arrow line extending from the diagonal signal routing cell 520 to the horizontal HBM ESD protection cell 560. The dashed arrow line pointing from the unselected output pin 534 is depicted with no shading to indicate that in the horizontal I/O cell use of the diagonal signal routing cell 520 no outbound signal is transmitted via the unselected output pin 534.

As discussed, the cell 526 may include an output driver of the horizontal I/O cell 550. In this manner, the latchup injectors of the horizontal I/O cell 550, namely the horizontal HBM ESD protection cell 560 and the output driver cell 526, are not situated next to the core region of the chip. For example, the horizontal HBM ESD protection cell 560 and the output driver cell 526 are separated from the core region by the cell 522 to prevent latchup in core circuits. The cell 522, as it is situated next to the core region, may include I/O circuitry other than the latchup injectors 560/526, such as level shifters, digital logic, pull logic, CDM ESD protection, and receiver. The intermediate cell 524 may include a pre-driver and control logic as it is situated between the level shifters and output driver from a signal flow perspective.

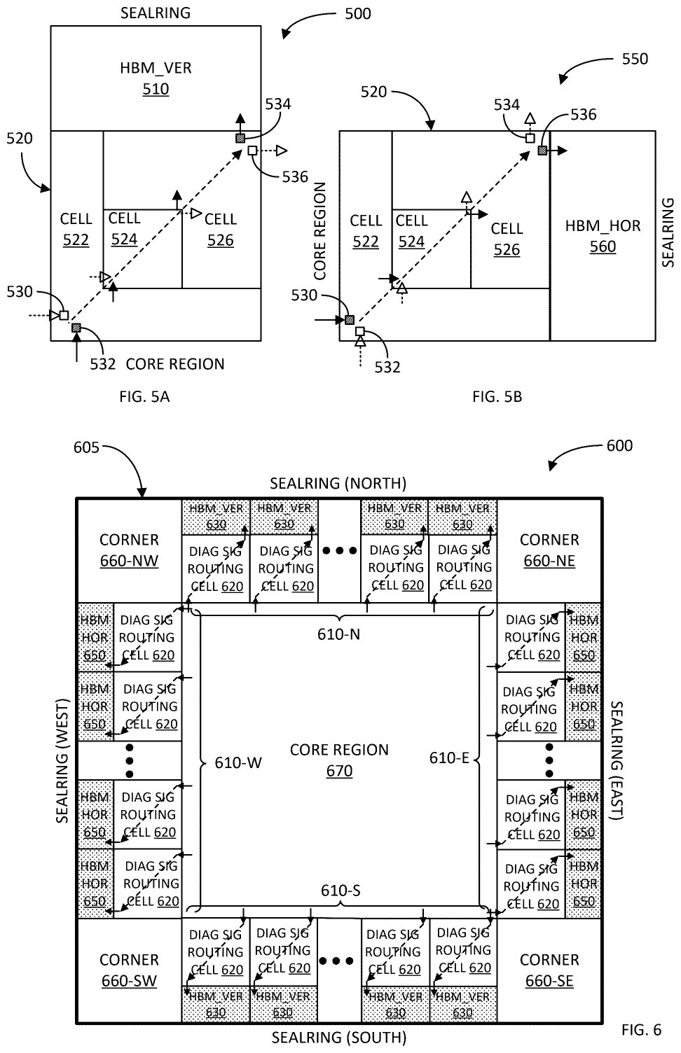

FIG. 6 illustrates a floorplan (layout) view of another example integrated circuit (IC) 600, such as a system on chip (SOC), (e.g., hereinafter “chip”) in accordance with another aspect of the disclosure. The chip 600 includes first and second linear arrays of vertical I/O circuits or cells 610-N/610-S extending horizontally parallel with and on the interior side of the north and south sides of the sealring 605 between pairs of corner cells 660-NW/660-NE and 660-SW/660-SE of the chip 600, respectively. Each of the vertical I/O cells 610-N/610-S may be implemented per vertical I/O cell 500 previously discussed, including a vertical HBM ESD protection cell 630 and a diagonal signal routing cell 620 vertically stacked between the sealring 605 and a core region 670 (where core circuits are situated) of the chip 600.

Similarly, the chip 600 includes first and second linear arrays of horizontal I/O circuits or cells 610-E/610-W extending vertically parallel with and on the interior chip side of the east and west sides of the sealring 605 between pairs of corner cells 660-NE/660-SE and 660-NW/660-SW of the chip 600, respectively. Each of the horizontal I/O cells 610-E/610-W may be implemented per horizontal I/O cell 550 previously discussed, including a horizontal HBM ESD protection cell 650 and the diagonal signal routing cell 620 horizontally stacked between the sealring 605 and the core region 670 of the chip 600.

As the diagonal signal routing cell 620 is common to both the vertical and horizontal I/O cells 610-N/610-S and 610-E/610-W, the time to design, layout, perform post-layout tweaks, perform functional, timing, and QA verification, etc. for the vertical and horizontal I/O cells 610-N/610-S and 610-E/610-W is significantly reduced (e.g., by approximately 50 percent).

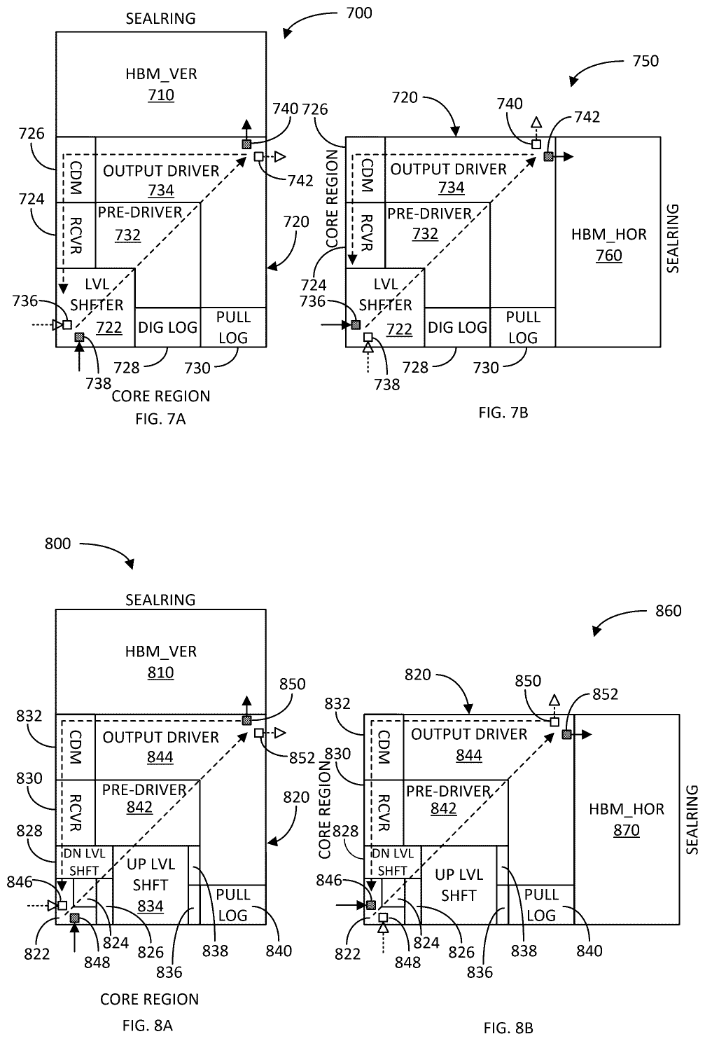

FIG. 7A illustrates a floorplan (layout) view of an example vertical I/O circuit or cell 700 in accordance with another aspect of the disclosure. The vertical I/O cell 700 may be an example more detailed implementation of the vertical I/O circuit 500. The vertical I/O cell 700 includes a vertical HBM ESD protection cell 710 (e.g., HBM_VER) stacked in a substantially vertically aligned manner with a diagonal signal routing cell 720 between a sealring and a core region of a chip.

The diagonal signal routing cell 720 includes a level shifter cell 722, which may be square or rectangular in shape, located at one of the core region side corners (e.g., the lower-left corner adjacent to the core region) of the vertical I/O cell 700. The vertical I/O cell 700 further includes a square-or rectangular-shaped CDM ESD protection cell 726 and a square-or rectangular-shaped receiver cell 724 situated in that order between the vertical HBM ESD protection cell 710 and the level shifter cell 722, and vertically positioned along the left horizontal boundary of the vertical I/O cell 700. Additionally, the vertical I/O cell 700 includes a square-or rectangular-shaped digital logic cell 728 and a square-or rectangular-shaped pull-logic cell 730 situated in that order between the level shifter cell 722 and the right horizontal boundary of the vertical I/O cell 700, and horizontally positioned along the lower (core region) boundary of the vertical I/O cell 700.

The diagonal signal routing cell 720 includes an L-shaped pre-driver cell 732 and an L-shaped output driver cell 734. The L-shaped pre-driver cell 732 includes a first leg extending horizontally between the receiver cell 724 and a second leg of the L-shaped output driver cell 734, and a second leg extending vertically between a first leg of the L-shaped output driver cell 734 and the digital logic cell 728. The first leg of the L-shaped output driver cell 734 extends horizontally between the CDM ESD protection cell 726 and the right horizontal boundary of the vertical I/O cell 700, and the second leg of the L-shaped output driver cell 734 extends vertically between the vertical HBM ESD protection cell 710 and the pull-logic cell 730. That is, the corner of the L-shaped output driver cell 734 coincides with the top-right corner of the diagonal signal routing cell 720 adjacent to the vertical HBM ESD protection cell 710.

In this example, the level shifter cell 722 includes a pair of selectable input pins 736 and 738 situated substantially at the lower-left corner of the diagonal signal routing cell 720. Similarly, the output driver cell 734 includes a pair of selectable output pins 740 and 742 situated substantially at a top-right corner of the diagonal signal routing cell 720 (e.g., proximate the intersection of the first and second legs of the L-shaped output driver cell 734). In the case of the vertical I/O cell 700, the selected one of the selectable input pins 736 and 738 may be the input pin 738 (as indicated with a dark shading) for coupling to a core circuit (as it is closer to the core region than the unselected input pin 736). The unselected input pin 736 is depicted with no shading. Also, in the case of the vertical I/O cell 700, the selected one of the selectable output pins 740 and 742 may be the output pin 740 (as indicated with a dark shading) for coupling to the vertical HBM ESD protection cell 710 (as it is closer to the vertical HBM ESD protection cell 710 than the unselected output pin 742). The unselected output pin 742 is depicted with no shading.

The level shifter cell 722, the pre-driver cell 732, and the output driver cell 734 are collectively configured to route an outbound signal from the selected input pin 738 to the selected output pin 740 diagonally across the diagonal signal routing cell 720, as indicated by the dashed arrow line. The vertical I/O cell 700 is configured to receive the outbound signal from a core circuit via the selected input pin 738 as indicated by the solid dark arrow line extending from the core region to the selected input pin 738. The dashed arrow line pointing to the unselected input pin 736 is depicted with no shading to indicate that in the vertical I/O cell use of the diagonal signal routing cell 720 no outbound signal is received via the unselected input pin 736. The diagonal signal routing cell 720 is configured to provide the outbound signal to the vertical HBM ESD protection cell 710 via the selected output pin 740 as indicated by the solid dark arrow line extending from the diagonal signal routing cell 720 into the vertical HBM ESD protection cell 710. The dashed arrow line pointing from the unselected output pin 742 is depicted with no shading to indicate that in the vertical I/O cell use of the diagonal signal routing cell 720 no outbound signal is transmitted via the unselected output pin 742. The outbound signal may collectively include the data signals S_{OCX}, S_{OPX}, S_{PTX}, and S_{TX} as described with reference to I/O circuit 100.

With regard to an inbound signal, the diagonal signal routing cell 720 may receive the inbound signal via the selected output pin 740 (e.g., in this case, functions as an input pin), and routed horizontally across the output driver cell 734 to the CDM ESD protection cell 726 and vertically downwards via the receiver cell 724 and the level shifter cell 722. As discussed further herein, the diagonal signal routing cell 720 may include additional selectable pins for routing the inbound signal to a core circuit via a selected one of those selectable pins. The inbound signal may collectively include the data signals S_{RX}, S_{IPX}, and S_{ICX}, as described with reference to I/O circuit 100.

Similar to the vertical I/O cell 500, the vertical I/O cell 700 includes the latchup injectors, namely vertical HBM ESD protection cell 710 and the output driver cell 734, not situated on the core region side of the vertical I/O cell 700. For example, the vertical HBM ESD protection cell 710 and the output driver cell 734 are separated from the core region by various combinations of the cells 726, 724, 722, 732, 728, and 730.

FIG. 7B illustrates a top view of an example horizontal I/O cell or circuit 750 in accordance with another aspect of the disclosure. The horizontal I/O cell 750 includes a horizontal HBM ESD protection cell 760 (e.g., HBM_HOR) stacked in a substantially horizontal aligned manner with the diagonal signal routing cell 720 between a sealring and a core region of a chip. Note that the horizontal I/O cell 750 uses the same (cell layout wise) diagonal signal routing cell 720 to route an outbound signal diagonally from a core circuit to the horizontal HBM ESD protection cell 760.

In the case of the horizontal I/O cell 750, the selected one of the selectable input pins 736 and 738 may be the input pin 736 (as indicated with a dark shading) for coupling to a core circuit (as it is closer to the core region than the unselected input pin 738). The unselected input pin 738 is depicted with no shading. Also, in the case of the horizontal I/O cell 750, the selected one of the selectable output pins 740 and 742 may be the output pin 742 (as indicated with a dark shading) for coupling to the horizontal HBM ESD protection cell 760 (as it is closer to the horizontal HBM ESD protection cell 760 than the unselected output pin 740). The unselected output pin 740 is depicted with no shading.

Similarly, the level shifter cell 722, the pre-driver cell 732, and the output driver cell 734 are collectively configured to route an outbound signal from the selected input pin 736 to the selected output pin 742 diagonally across the diagonal signal routing cell 720, as indicated by the dashed arrow line. The horizontal I/O cell 750 is configured to receive the outbound signal from a core circuit via the selected input pin 736 as indicated by the solid dark arrow line extending from the core region to the selected input pin 736. The dashed arrow line pointing to the unselected input pin 738 is depicted with no shading to indicate that in the horizontal I/O cell use of the diagonal signal routing cell 720 no outbound signal is received via the unselected input pin 738. The diagonal signal routing cell 720 is configured to provide the outbound signal to the horizontal HBM ESD protection cell 760 via the selected output pin 742 as indicated by the dark arrow line extending from the diagonal signal routing cell 720 into the horizontal HBM ESD protection cell 760. The dashed arrow line pointing from the unselected output pin 740 is depicted with no shading to indicate that in the horizontal I/O cell use of the diagonal signal routing cell 720 no outbound signal is transmitted via the unselected output pin 740. The outbound signal may collectively include the data signals S_{OCX}, S_{OPX}, S_{PTX}, and S_{TX} as described with reference to I/O circuit 100.

With regard to an inbound signal, the diagonal signal routing cell 720 may receive the inbound signal via the selected output pin 742 (e.g., in this case, functions as an input pin), and routed horizontally across the output driver cell 734 to the CDM ESD protection cell 726 and vertically downwards via the receiver cell 724 and the level shifter cell 722. As discussed further herein, the diagonal signal routing cell 720 may include additional selectable pins for routing the inbound signal to a core circuit via the selected one of those selectable pins. The inbound signal may collectively include the data signals S_{RX}, S_{IPX}, and S_{ICX}, as described with reference to I/O circuit 100.

Similar to the vertical I/O cell 700, the horizontal I/O cell 750 includes the latchup injectors, namely horizontal HBM ESD protection cell 760 and the output driver cell 734, not situated next to the core region side of the horizontal I/O cell 750. For example, the horizontal HBM ESD protection cell 760 and the output driver cell 734 are separated from the core region side by various combinations of the cells 726, 724, 722, 732, 728, and 730.

FIG. 8A illustrates a floorplan (layout) view of an example vertical I/O circuit or cell 800 in accordance with another aspect of the disclosure. The vertical I/O cell 800 may be an example more detailed implementation of the vertical I/O circuit 500. The vertical I/O cell 800 includes a vertical HBM ESD protection cell 810 (e.g., HBM_VER) stacked in a substantially vertically aligned manner with a diagonal signal routing cell 820 between a sealring and a core region of a chip.

The diagonal signal routing cell 820 includes an L-shaped antenna diode cell 822 located at one of the core region side corners (e.g., the lower-left corner adjacent to the core region) of the vertical I/O cell 800. The vertical I/O cell 800 further includes a square-or rectangular-shaped digital logic cell 824 including left and lower boundaries situated to the right of and above first and second legs of the L-shaped antenna diode cell 822. The diagonal signal routing cell 820 also includes a square-or rectangular shaped multiplexer cell 826 situated to the right of the digital logic cell 824 and the second leg of the L-shaped antenna diode cell 822, and a lower boundary coinciding with the lower (core region side) boundary of the diagonal signal routing cell 820.

The diagonal signal routing cell 820 further includes a square or rectangular shaped down level shifter cell 828 including a left boundary coinciding with the left horizontal boundary of the diagonal signal routing cell 820, and a lower boundary above the first leg of the L-shaped antenna diode cell 822, the digital logic cell 824, and the multiplexer cell 826. Further, the digital signal routing cell 820 includes an up level shifter cell 834 to the right of the down level shifter cell 828 and the multiplexer cell 826. Additionally, the digital signal routing cell 820 includes a demultiplexer cell 838 vertically stacked with another digital logic cell 836, both to the right of the up level shifter cell 834, where the lower boundary of the digital logic cell 836 coincides with the lower (core region side) boundary of the diagonal signal routing cell 820.

Further, the diagonal signal routing cell 820 includes a pull-logic cell 840 situated between the digital logic cell 836 and the right horizontal boundary of the diagonal signal routing cell 820, where the lower boundary of the pull-logic 840 coincides with the lower (core region side) boundary of the diagonal signal routing cell 820. The diagonal signal routing cell 820 also includes a CDM ESD protection cell 832 vertically stacked with a receiver cell 830 between the vertical HBM ESD protection cell 810 and the down level shifter cell 828, where the left boundaries of the CDM ESD protection cell 832 and the receiver cell 830 coincide with the left boundary of the diagonal signal routing cell 820.

The diagonal signal routing cell 820 includes a square-or rectangular pre-driver cell 842 and an L-shaped output driver cell 844. The pre-driver cell 842 is sandwiched between the receiver cell 830 and a second leg of the L-shaped output driver 844 in the horizontal direction, and sandwiched between a first leg of the L-shaped output driver 844 and a portion of the down level shifter cell 828, the up level shifter cell 834, and the demultiplexer cell 838 in the vertical direction. The first leg of the L-shaped output driver cell 844 is sandwiched between the CDM ESD protection cell 832 and the right horizontal boundary of the diagonal signal routing cell 820 in the horizontal direction, and the second leg of the L-shaped output driver cell 844 is sandwiched between the vertical HBM ESD protection cell 810 and the pull-logic cell 840 in the vertical direction. That is, the corner of the L-shaped output driver cell 844 coincides with the top-right corner of the diagonal signal routing cell 820 adjacent to the vertical HBM ESD protection cell 810.

In this example, the antenna diode cell 822 includes a pair of selectable input pins 846 and 848 situated substantially at the lower-left corner of the diagonal signal routing cell 820. Similarly, the output driver cell 844 includes a pair of selectable output pins 850 and 852 situated substantially at a top-right corner of the diagonal signal routing cell 820 (e.g., proximate the intersection of the first and second legs of the output driver cell 844). In the case of the vertical I/O cell 800, the selected one of the selectable input pins 846 and 848 may be the input pin 848 (as indicated with a dark shading) for coupling to a core circuit (as it is closer to the core region than the unselected input pin 846). The unselected input pin 846 is depicted with no shading. Also, in the case of the vertical I/O cell 800, the selected one of the selectable output pins 850 and 852 may be the output pin 850 (as indicated with a dark shading) for coupling to the vertical HBM ESD protection cell 810 (as it is closer to the vertical HBM ESD protection cell 810 than the unselected output pin). The unselected output pin 852 is depicted with no shading.

The antenna diode cell 822, the digital logic cell 824, the up level shifter cell 834, the pre-driver cell 842, and the output driver cell 844 are collectively configured to route an outbound signal from the selected input pin 848 to the selected output pin 850 diagonally across the diagonal signal routing cell 820, as indicated by the dashed arrow line. The vertical I/O cell 800 is configured to receive the outbound signal from a core circuit via the selected input pin 848 as indicated by the solid dark arrow line extending from the core region to the selected input pin 848. The dashed arrow line pointing to the unselected input pin 846 is depicted with no shading to indicate that in the vertical I/O cell use of the diagonal signal routing cell 820 no outbound signal is received via the unselected input pin 846. The diagonal signal routing cell 820 is configured to provide the outbound signal to the vertical HBM ESD protection cell 810 via the selected output pin 850 as indicated by the solid dark arrow line extending from the diagonal signal routing cell 820 into the vertical HBM ESD protection cell 810. The dashed arrow line pointing from the unselected output pin 852 is depicted with no shading to indicate that in the vertical I/O cell use of the diagonal signal routing cell 820 no outbound signal is transmitted via the unselected output pin 852. The outbound signal may collectively include the data signals S_{OCX}, S_{OPX}, S_{PTX}, and S_{TX} as described with reference to I/O circuit 100.

With regard to an inbound signal, the diagonal signal routing cell 820 may receive the inbound signal via the selected output pin 850 (e.g., in this case, functions as an input pin), and routed horizontally across the output driver cell 844 to the CDM ESD protection cell 832 and vertically downwards via the receiver cell 830 and the level shifter 828. As discussed further herein, the diagonal signal routing cell 820 may include additional selectable pins for routing the inbound signal to a core circuit via the selected one of those selectable pins. The inbound signal may collectively include the data signals S_{RX}, S_{IPX}, and S_{ICX}, as described with reference to I/O circuit 100.

Similar to the vertical I/O cell 500, the vertical I/O cell 800 includes the latchup injectors, namely vertical HBM ESD protection cell 810 and the output driver cell 844, not situated on the core region side of the vertical I/O cell 800. For example, the vertical HBM ESD protection cell 810 and the output driver cell 844 are separated from the core region by various combinations of the cells 822 to 842.

FIG. 8B illustrates a top view of an example horizontal I/O cell or circuit 860 in accordance with another aspect of the disclosure. The horizontal I/O cell 860 includes a horizontal HBM ESD protection cell 870 (e.g., HBM_HOR) stacked in a substantially horizontal aligned manner with the diagonal signal routing cell 820 between a sealring and a core region of a chip. Note that the horizontal I/O cell 860 uses the same (cell layout wise) diagonal signal routing cell 820 to route an outbound signal diagonally from a core circuit to the horizontal HBM ESD protection cell 870.

In the case of the horizontal I/O cell 860, the selected one of the selectable input pins 846 and 848 may be the input pin 846 (as indicated with a dark shading) for coupling to a core circuit (as it is closer to the core region than the unselected input pin 848). The unselected input pin 848 is depicted with no shading. Also, in the case of the horizontal I/O cell 860, the selected one of the selectable output pins 850 and 852 may be the output pin 852 (as indicated with a dark shading) for coupling to the horizontal HBM ESD protection cell 870 (as it is closer to the horizontal HBM ESD protection cell 870 than the unselected output pin 850). The unselected output pin 850 is depicted with no shading.

Similarly, the antenna diode cell 822, the digital logic cell 824, the up level shifter cell 834, the pre-driver cell 842, and the output driver cell 844 are collectively configured to route an outbound signal from the selected input pin 846 to the selected output pin 852 diagonally across the diagonal signal routing cell 820, as indicated by the dashed arrow line. The horizontal I/O cell 860 is configured to receive the outbound signal from a core circuit via the selected input pin 846 as indicated by the solid dark arrow line extending from the core region to the selected input pin 846. The dashed arrow line pointing to the unselected input pin 848 is depicted with no shading to indicate that in the horizontal I/O cell use of the diagonal signal routing cell 820 no outbound signal is received via the unselected input pin 848. The diagonal signal routing cell 820 is configured to provide the outbound signal to the horizontal HBM ESD protection cell 870 via the selected output pin 852 as indicated by the solid dark arrow line extending from the diagonal signal routing cell 820 into the horizontal HBM ESD protection cell 870. The dashed arrow line pointing from the unselected output pin 850 is shown with no shading to indicate that in the horizontal I/O cell use of the diagonal signal routing cell 820 no outbound signal is transmitted via the unselected output pin 850. The outbound signal may collectively include the data signals S_{OCX}, S_{OPX}, S_{PTX}, and S_{TX} as described with reference to I/O circuit 100.

With regard to an inbound signal, the diagonal signal routing cell 820 may receive the inbound signal via the selected output pin 852 (e.g., in this case, functions as an input pin), and routed horizontally across the output driver cell 844 to the CDM ESD protection cell 832 and vertically downwards via the receiver cell 830, the down level shifter cell 828, and the antenna diode cell 822. As discussed further herein, the diagonal signal routing cell 820 may include additional selectable pins for routing the inbound signal to a core circuit via the selected one of those selectable pins. The inbound signal may collectively include the data signals S_{RX}, S_{IPX}, and S_{ICX}, as described with reference to I/O circuit 100.

Similar to the vertical I/O cell 800, the horizontal I/O cell 860 includes the latchup injectors, namely horizontal HBM ESD protection cell 870 and the output driver cell 844, not situated on the core region side of the horizontal I/O cell 860. For example, the horizontal HBM ESD protection cell 870 and the output driver cell 844 are separated from the core region by various combinations of the cells 822 to 842.

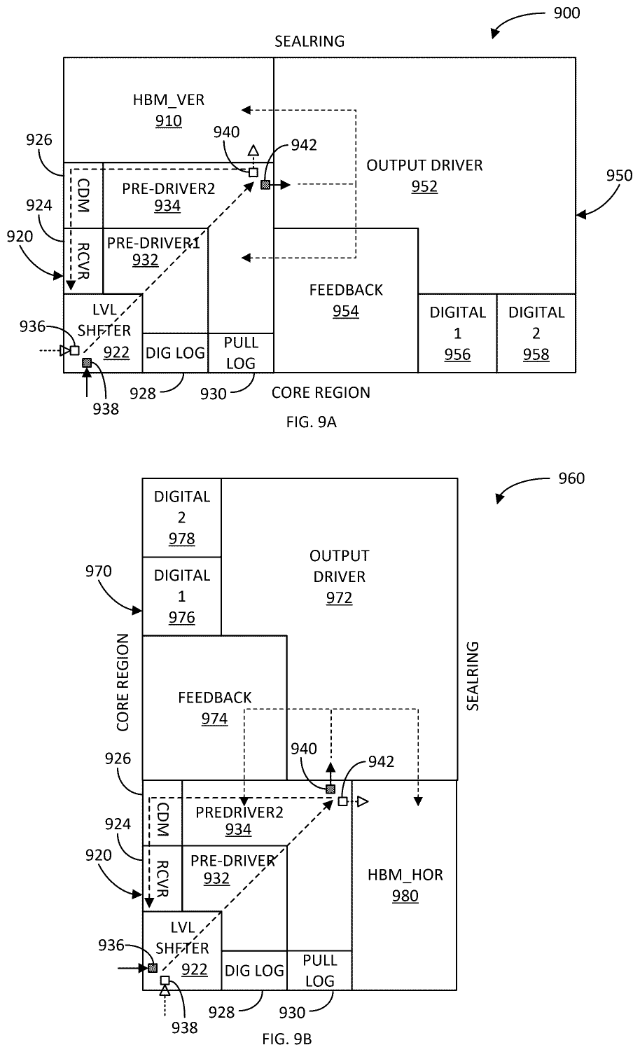

FIG. 9A illustrates a floorplan (layout) view of an example vertical I/O circuit or cell 900 in accordance with another aspect of the disclosure. The vertical I/O cell 900 includes two pre-drivers used in different modes (e.g., in a general purpose input/output (GPIO) mode and a radio frequency front-end (RFFE) mode). In the RFFE mode, a feedback circuit is used to control the second pre-driver based on a transmit signal S_{TX} generated by an output driver. In particular, the vertical I/O circuit 900 includes a vertical HBM ESD protection cell 910, a diagonal signal routing cell 920, and an additional I/O cell 950.

The diagonal signal routing cell 920 includes a level shifter cell 922, which may be square or rectangular in shape, located at one of the core region side corners (e.g., the lower-left corner adjacent to the core region) of the diagonal signal routing cell 920. The diagonal signal routing cell 920 further includes a square-or rectangular-shaped CDM ESD protection cell 926 and a square-or rectangular-shaped receiver cell 924 situated in that order between the vertical HBM ESD protection cell 910 and the level shifter cell 922, and vertically positioned along the left horizontal boundary of the diagonal signal routing cell 920. Additionally, the vertical I/O cell 900 includes a square-or rectangular-shaped digital logic cell 928 and a square-or rectangular-shaped pull-logic cell 930 situated in that order between the level shifter cell 922 and the right horizontal boundary of the diagonal signal routing cell 920, and horizontally positioned along the lower (core region side) boundary of the vertical I/O cell 900.

The diagonal signal routing cell 920 includes a first L-shaped pre-driver1 cell 932 and a second L-shaped pre-driver2 cell 934. The first L-shaped pre-driver1 cell 932 includes a first leg extending horizontally between the receiver cell 924 and a second leg of the second L-shaped pre-driver2 934, and a second leg extending vertically between a first leg of the second L-shaped pre-driver2 cell 934 and the digital logic cell 928. The first leg of the second L-shaped pre-driver2 cell 934 extends horizontally between the CDM ESD protection cell 926 and the right horizontal boundary of the diagonal signal routing cell 920, and the second leg of the second L-shaped pre-driver2 cell 934 extends vertically between the vertical HBM ESD protection cell 910 and the pull-logic cell 930. That is, the corner of the L-shaped second pre-driver cell 934 coincides with the top-right corner of the diagonal signal routing cell 920 adjacent to the vertical HBM ESD protection cell 910.

The additional I/O circuit 950 includes an L-shaped output driver cell 952, a square-or rectangular-shaped feedback cell 954, a first square-or rectangular-shaped digital cell1 956, and a second square-or rectangular-shaped digital cell2 958. The L-shaped output driver cell 952 includes a first leg bounded on a left side by the vertical HBM ESD protection cell 910 and an upper portion of the second pre-driver2 cell 934, and bounded on the right by the right boundary of the vertical I/O cell 900. The L-shaped output driver cell 952 includes a second leg situated between the upper (sealring side) boundary of the vertical I/O cell 900 and the horizontally-stacked first and second digital cells1-2 956 and 958.

The feedback cell 954 is bounded on the left by portions of the second pre-driver2 cell 934 and pull-logic cell 930, bounded on top by the first leg of the L-shaped output driver 952, and bounded on the right by the second leg of the L-shaped output driver 952 and the first digital cell1 956, wherein its lower boundary coincides with the lower (core region side) boundary of the vertical I/O cell 900. As indicated, the first and second digital cells1-2 956 and 958 are horizontally stacked between the feedback cell 954 and the right horizontal boundary of the vertical I/O cell 900, with their lower boundaries coinciding with the lower (core region side) boundary of the vertical I/O cell 900.

In this example, the level shifter cell 922 includes a pair of selectable input pins 936 and 938 situated proximate the lower-left corner of the diagonal signal routing cell 920. Similarly, the second pre-driver2 cell 934 includes a pair of selectable output pins 940 and 942 situated proximate a top-right corner (opposite to the lower-left corner) of the diagonal signal routing cell 920 (e.g., proximate the intersection of the first and second legs of the second pre-driver2 cell 934). In the case of the vertical I/O cell 900, the selected one of the selectable input pins 936 and 938 may be the input pin 938 (as indicated with a dark shading) for coupling to a core circuit (as it is closer to the core region than the unselected input pin 936). The unselected input pin 936 is depicted with no shading. Also, in the case of the vertical I/O cell 900, the selected one of the selectable output pins 940 and 942 may be the output pin 942 (as indicated with a dark shading) for coupling to the output driver cell 952 (as it is closer to the output driver cell 952 than the unselected output pin 940). The unselected output pin 940 is depicted with no shading.

The level shifter cell 922, the first pre-driver1 cell 932, and the second pre-driver2 cell 934 are collectively configured to route an outbound signal from the selected input pin 938 to the selected output pin 942 diagonally across the diagonal signal routing cell 920, as indicated by the dashed arrow line. The vertical I/O cell 900 is configured to receive the outbound signal from a core circuit via the selected input pin 938 as indicated by the solid dark arrow line extending from the core region to the selected input pin 938. The dashed arrow line pointing to the unselected input pin 936 is depicted with no shading to indicate that in the vertical I/O cell use of the diagonal signal routing cell 920 no outbound signal is received via the unselected input pin 936. The diagonal signal routing cell 920 is configured to provide the outbound signal to the output driver cell 952 via the selected output pin 942 as indicated by the solid dark arrow line extending from the diagonal signal routing cell 920 into the output driver cell 952. The dashed arrow line pointing from the unselected output pin 940 is depicted with no shading to indicate that in the vertical I/O cell use of the diagonal signal routing cell 920 no outbound signal is transmitted via the unselected output pin 940. The output driver cell 952 may then provide the outbound signal to the vertical HBM ESD protection cell 910, and a feedback signal to the second pre-driver2 cell 934 via the feedback cell 954. The outbound signal may collectively include the data signals S_{OCX}, S_{OPX}, S_{PTX}, and S_{TX} as described with reference to I/O circuit 100.

With regard to an inbound signal, the diagonal signal routing cell 920 may receive the inbound signal via the selected output pin 942 (e.g., in this case, functions as an input pin), and routed horizontally across the second pre-driver2 cell 934 to the CDM ESD protection cell 926 and vertically downwards via the receiver cell 924 and the level shifter cell 922. As discussed further herein, the level shifter cell 922 may include another set of selectable pins for routing the inbound signal to a core circuit via the selected one of those selectable pins. The inbound signal may collectively include the data signals S_{RX}, S_{IPX}, and S_{ICX}, as described with reference to I/O circuit 100.

Similar to the vertical I/O cell 500, the vertical I/O cell 900 includes the latchup injectors, namely vertical HBM ESD protection cell 910 and the output driver cell 952, not situated on the core region side of the vertical I/O cell 900. For example, the vertical HBM ESD protection cell 910 is separated from the core region by various combinations of the cells 922 to 934. The output driver cell 952 is separated from the core region by the feedback cell 954 and the first and second digital cells1-2 956 and 958.

FIG. 9B illustrates a top view of an example horizontal I/O cell or circuit 960 in accordance with another aspect of the disclosure. The horizontal I/O cell 960 includes a horizontal HBM ESD protection cell 980 (e.g., HBM_HOR) stacked in a substantially horizontal aligned manner with the diagonal signal routing cell 920 between a sealring and a core region of a chip. Note that the horizontal I/O cell 960 uses the same (cell layout wise) diagonal signal routing cell 920 to route an outbound signal diagonally from a core circuit to the horizontal HBM ESD protection cell 980 via an output driver cell 972 of an additional I/O circuit 970.

The additional I/O circuit 950 includes an L-shaped output driver cell 972, a square-or rectangular-shaped feedback cell 974, a first square-or rectangular-shaped digital cell1 976, and a second square-or rectangular-shaped digital cell2 978. The L-shaped output driver cell 972 includes a first leg bounded on a left side by the vertically-stacked first and second digital cells1-2 976 and 978, and on the right by the right (sealring side) boundary of the horizontal I/O cell 960. The L-shaped output driver cell 972 includes a second leg situated between the upper boundary of the horizontal I/O cell 960 and a portion of the second pre-driver2 cell 934 and horizontal HBM ESD protection cell 980.

The feedback cell 954 is bounded on the left by the left (core region side) boundary of the horizontal I/O cell 960, on top by the first digital cell1 976 and the first leg of the L-shaped output driver 952, bounded on the right by the second leg of the L-shaped output driver 972, and on the bottom by the CDM ESD protection cell 926 and second pre-driver2 cell 934. As indicated, the first and second digital cells1-2 976 and 978 are vertically stacked between the top boundary of the horizontal I/O cell 960 and the feedback cell 974, with their left boundaries coinciding with the left (core region side) boundary of the horizontal I/O cell 960.

In the case of the horizontal I/O cell 960, the selected one of the selectable input pins 936 and 938 may be the input pin 936 (as indicated with a dark shading) for coupling to a core circuit (as it is closer to the core region than the unselected input pin 938). The unselected input pin 938 is depicted with no shading. Also, in the case of the horizontal I/O cell 960, the selected one of the selectable output pins 940 and 942 may be the output pin 940 (as indicated with a dark shading) for coupling to the output driver cell 972 (as it is closer to the output driver cell 972 than the unselected input pin 942). The unselected output pin 942 being indicated with no shading. The output driver cell 972 may then provide the outbound signal to the horizontal HBM ESD protection cell 980, and a feedback signal to the second pre-driver2 cell 934 via the feedback cell 974. The outbound signal may collectively include the data signals S_{OCX}, S_{OPX}, S_{PTX}, and S_{TX} as described with reference to I/O circuit 100.

Similarly, the level shifter cell 922, the first pre-driver1 cell 932, and the second pre-driver2 cell 934 are collectively configured to route an outbound signal from the selected input pin 936 to the selected output pin 940 diagonally across the diagonal signal routing cell 920, as indicated by the dashed arrow line. The horizontal I/O cell 960 is configured to receive the outbound signal from a core circuit via the selected input pin 936 as indicated by the dark arrow line extending from the core region to the selected input pin 936. The dashed arrow line pointing to the unselected input pin 938 is depicted with no shading to indicate that in the horizontal I/O cell use of the diagonal signal routing cell 920 no outbound signal is received via the unselected input pin 938. The diagonal signal routing cell 920 is configured to provide the outbound signal to the output driver cell 972 via the selected output pin 940 as indicated by the dark arrow line extending from the diagonal signal routing cell 920 into the output driver cell 972. The dashed arrow line pointing from the unselected output pin 942 is depicted with no shading to indicate that in the horizontal I/O cell use of the diagonal signal routing cell 920 no outbound signal is transmitted via the unselected output pin 942. The outbound signal may collectively include the data signals S_{OCX}, S_{OPX}, S_{PTX}, and S_{TX} as described with reference to I/O circuit 100.

With regard to an inbound signal, the diagonal signal routing cell 920 may receive the inbound signal via the selected output pin 940 (e.g., in this case, functions as an input pin), and routed horizontally across the second pre-driver2 cell 934 to the CDM ESD protection cell 926 and vertically downwards via the receiver cell 924 and the level shifter cell 922. As discussed, the level shifter cell 922 may include another set of selectable pins for routing the inbound signal to a core circuit via the selected one of the selectable pins. The inbound signal may collectively include the data signals S_{RX}, S_{IPX}, and S_{ICX}, as described with reference to I/O circuit 100.

Similar to the vertical I/O cell 900, the horizontal I/O cell 960 includes the latchup injectors, namely horizontal HBM ESD protection cell 980 and the output driver cell 972, not situated on the core region side of the horizontal I/O cell 960. For example, the horizontal HBM ESD protection cell 980 is separated from the core region by various combinations of the cells 922 to 934. The output driver cell 972 is separated from the core region by the feedback cell 974 and the first and second digital cells1-2 976 and 978.

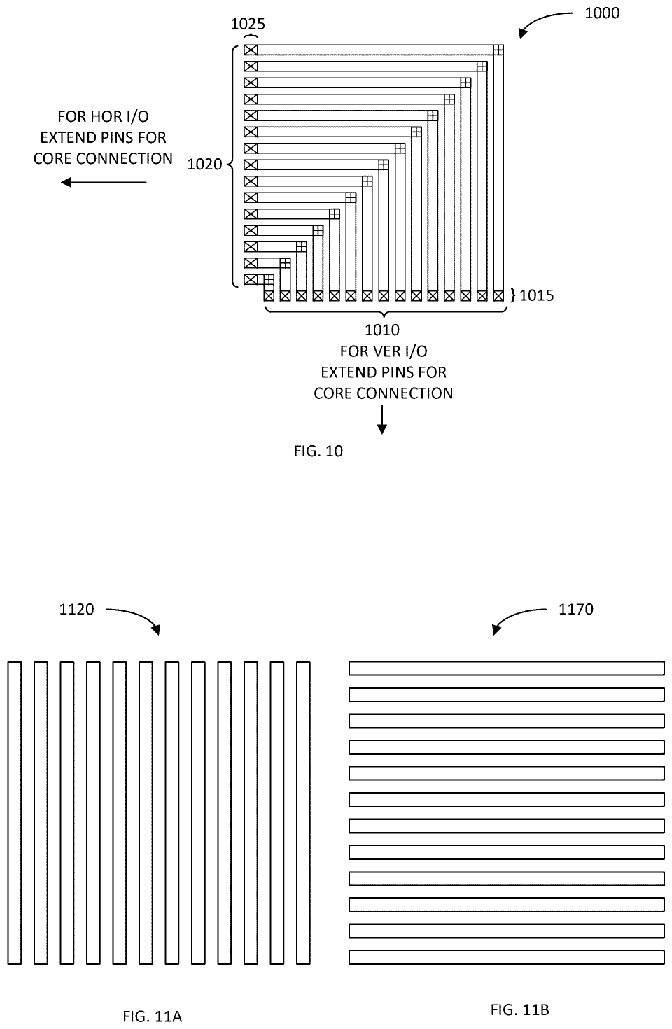

FIG. 10 illustrates a floor plan view of a set of metal traces 1000 including selectable core pins for connection to core circuits for vertical and horizontal I/O circuits or cells in accordance with another aspect of the disclosure. The set of metal traces 1000 includes a set of vertical metal traces 1010 including selectable core pins 1015 at lower ends thereof, respectively. The set of metal traces 1000 includes a set of horizontal metal traces 1020 including selectable core pins 1025 at left horizontal ends thereof, respectively. The set of vertical metal traces 1010 may be on a different metal layer as the set of horizontal metal traces 1020.

To couple a vertical I/O cell to core circuits, such as any of the vertical I/O cells 500, 700, 800, and 900 previously discussed, the selectable core pins 1015 of the set of vertical metal traces 1010 are selected or activated by extending them vertically downwards to provide the pin connections to the core circuits. The unselected core pins 1025 are not extended. To couple a horizontal I/O cell to core circuits, such as any of the horizontal I/O cells 550, 750, 860, and 970 previously discussed, the selectable core pins 1025 are selected or activated by extending them horizontally (e.g., to the left) to provide the pins for electrical connection to the core circuits. The unselected core pins 1015 are not extended.

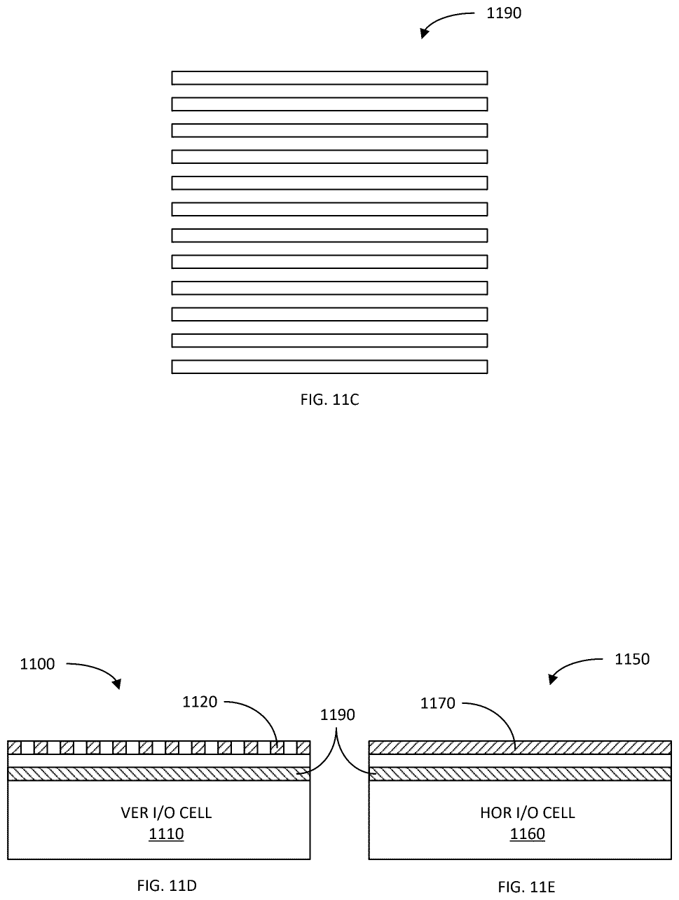

FIG. 11A illustrates a floorplan (layout) view of an example set of upper metal traces 1120 associated with a vertical I/O circuit or cell in accordance with another aspect of the disclosure. The set of upper metal traces 1120 electrically couple the corresponding vertical HBM ESD protection cell to an I/O pin for a vertical I/O cell, such as any of the vertical I/O cells 500, 700, 800, and 900 previously discussed. As shown, the set of upper metal traces 1120 extend in the vertical direction; and as such, may present a certain parasitic to the underlying vertical I/O cell.

FIG. 11B illustrates a floorplan view of an example set of upper metal traces 1170 associated with a horizontal I/O circuit or cell in accordance with another aspect of the disclosure. The set of upper metal traces 1170 electrically couple the corresponding horizontal HBM ESD protection cell to an I/O pin for a horizontal I/O cell, such as any of the horizontal I/O cells 550, 750, 860, and 960 previously discussed. As shown, the set of upper metal traces 1170 extend in the horizontal direction; and as such, may present another certain parasitic to the underlying horizontal I/O cell, which may be different than the parasitic presented by the set of upper metal traces 1120 to the underlying vertical I/O cell.

FIG. 11C illustrates a floorplan view of an example parasitic equalizing shield 1190 for both vertical and horizontal I/O circuits or cells in accordance with another aspect of the disclosure. As discussed above, the set of vertical upper metal traces 1120 may present a certain parasitic to an underlying vertical I/O cell that may be different than the parasitic presented by the set of horizontal upper metal traces 1170 to an underlying horizontal I/O cell. To better equalize the parasitic, the shield may be situated between the vertical I/O cell and the set of vertical upper metal traces 1120, and between the horizontal I/O cell and the set of horizontal metal traces 1170. The shield 1190 has the same metal pattern for both the vertical and horizontal I/O cells so that they see substantially the same parasitic. In this example, the shield 1190 includes a set of horizontal lines, but could include a set of vertical lines, or other metal pattern.

FIG. 11D illustrates a side cross sectional view of an example portion of an integrated circuit (IC) 1100, such as a system on chip (SOC), (hereinafter “chip”) in accordance with another aspect of the disclosure. The chip 1100 includes a vertical I/O cell 1110, the shield 1190 situated on a metal layer over the vertical I/O cell 1110, and the set of vertical upper metal traces 1120 situated on a metal layer over the shield 1190. In such configuration, the vertical I/O cell 1110 sees the parasitic of the shield 1190 instead of or significantly more than the parasitic of the set of vertical upper metal traces 1120.

FIG. 11E illustrates a side cross sectional view of an example portion of an integrated circuit (IC) 1150, such as a system on chip (SOC), (hereinafter “chip”) in accordance with another aspect of the disclosure. The chip 1150 includes a horizontal I/O cell 1160, the shield 1190 situated on a metal layer over the horizontal I/O cell 1160, and the set of horizontal upper metal traces 1170 situated on a metal layer over the shield 1190. In such configuration, the horizontal I/O cell 1160 sees the parasitic of the shield 1190 instead of or significantly more than the parasitic of the set of horizontal upper metal traces 1170.

The following provides an overview of aspects of the present disclosure:

Aspect 1: An integrated circuit, comprising: a sealring; a core region; and a first input/output (I/O) cell, comprising: a first diagonal signal routing cell; and a first electrostatic discharge (ESD) protection cell stacked with the first diagonal signal routing cell between the sealring and the core region, wherein the first diagonal signal routing cell is configured to route a first outbound signal from a first pin located substantially at a first corner of the first diagonal signal routing cell adjacent to the core region to a second pin located substantially at a second corner of the first diagonal signal routing cell adjacent to the first ESD protection cell.

Aspect 2: The integrated circuit of aspect 1, wherein the first diagonal signal routing cell includes an output driver cell, wherein the second pin is located within the output driver cell.

Aspect 3: The integrated circuit of aspect 2, wherein the output driver cell is L-shaped including a corner coincident with the second corner of the first diagonal signal routing cell.

Aspect 4: The integrated circuit of aspect 2 or 3, wherein the first diagonal signal routing cell includes a set of one or more cells separating the output driver cell and the first ESD protection cell from the core region.

Aspect 5: The integrated circuit of any one of aspects 1-4, wherein the first diagonal signal routing cell includes an L-shaped cell including a corner coincident with the first corner of the first diagonal signal routing cell.

Aspect 6: The integrated circuit of any one of aspects 1-5, wherein the first diagonal signal routing cell includes a level shifter cell, a pre-driver cell, and an output driver cell, wherein the first outbound signal is routed from the first pin to the second pin via the level shifter cell, the pre-driver cell, and the output driver cell.

Aspect 7: The integrated circuit of any one of aspects 1-6, wherein: the first pin is a selected one of a first pair of selectable pins, the selected first pin situated closer to the core region than an unselected one of the first pair of selectable pins; and the second pin is a selected one of a second pair of selectable pins, the selected second pin situated closer to the first ESD protection cell than an unselected one of the second pair of selectable pins.

Aspect 8: The integrated circuit of any one of aspects 1-7, wherein the first pin is coupled to a first core circuit within the core region, and the second pin is coupled to the first ESD protection cell.

Aspect 9: The integrated circuit of aspect 8, wherein the first diagonal signal routing cell is configured to route an inbound signal from the second pin to a third pin coupled to a second core circuit within the core region.

Aspect 10: The integrated circuit of aspect 9, wherein the first diagonal signal routing cell includes a second ESD protection cell and a receiver cell, wherein the inbound signal is routed to the third pin via the second ESD protection cell and the receiver cell.

Aspect 11: The integrated circuit of any one of aspects 1-10, wherein the first ESD protection cell is stacked with the first diagonal signal routing cell in a vertical direction between a north side or a south side of the sealring and the core region.

Aspect 12: The integrated circuit of aspect 11, further comprising a second I/O cell, comprising: a second diagonal signal routing cell; and a second ESD protection cell stacked with the second diagonal signal routing cell in a horizontal direction between an east side or a west side of the sealring and the core region, wherein the second diagonal signal routing cell is configured to route a second outbound signal from a first pin located substantially at a first corner of the second diagonal signal routing cell adjacent to the core region to a second pin located substantially at a second corner of the second diagonal signal routing cell adjacent to the second ESD protection cell.

Aspect 13: The integrated circuit of aspect 12, wherein the second diagonal signal routing cell has substantially the same cell layout as the first diagonal signal routing cell.

Aspect 14: The integrated circuit of aspect 13, wherein: the first diagonal signal routing cell includes a first and a second selectable pins, the first pin of the first diagonal signal routing cell being the first selectable pin; and the second diagonal signal routing cell includes a third and a fourth selectable pins located in the same layout location as the first and second selectable pins of the first diagonal signal routing cell, respectively, the first pin of the second diagonal signal routing cell being the fourth selectable pin.

Aspect 15: The integrated circuit of aspect 13 or 14, wherein: the first diagonal signal routing cell includes a first and a second selectable pins, the second pin of the first diagonal signal routing cell being the first selectable pin; and the second diagonal signal routing cell includes a third and a fourth selectable pins located in the same layout location as the first and second selectable pins of the first diagonal signal routing cell, respectively, the second pin of the second diagonal signal routing cell being the fourth selectable pin.

Aspect 16: The integrated circuit of any one of aspects 13-15, further comprising: a first set of metal traces extending parallel in the vertical direction, wherein the first set of metal traces overlie the first I/O cell; a first shield situated between the first set of metal traces and the first I/O cell; a second set of metal traces extending parallel along the horizontal direction, wherein the second set of metal traces overlie the second I/O cell; and a second shield situated between the second set of metal traces and the second I/O cell, wherein a layout of the first shield is substantially the same as a layout of the second shield.

Aspect 17: The integrated circuit of any one of aspects 1 and 5-16, wherein the first diagonal signal routing cell includes a first pre-driver cell and a second pre-driver cell, wherein the second pin is located within the second pre-driver cell.

Aspect 18: The integrated circuit of aspect 17, wherein the first I/O cell further includes an output driver cell, wherein the second pin is coupled to the first ESD protection cell via the output driver cell.

Aspect 19: An integrated circuit, comprising: a square or rectangular shaped sealring including a north side, an east side, a south side, and a west side; a core region situated within the sealring; a first linear array of vertical input/output (I/O) cells extending parallel with the north side of the sealring, and situated between the north side of the sealring and the core region, wherein each of the vertical I/O cells of the first linear array includes a first electrostatic discharge (ESD) protection cell stacked with a first diagonal signal routing cell in a north-to-south vertical direction, respectively; a second linear array of vertical I/O cells extending parallel with the south side of the sealring, and situated between the south side of the sealring and the core region, wherein each of the vertical I/O cells of the second linear array includes a second ESD protection cell stacked with a second diagonal signal routing cell in a south-to-north vertical direction, respectively; a first linear array of horizontal I/O cells extending parallel with the east side of the sealring, and situated between the east side of the sealring and the core region, wherein each of the horizontal I/O cells of the first linear array includes a third ESD protection cell stacked with a third diagonal signal routing cell in an east-to-west horizontal direction, respectively; and a second linear array of horizontal I/O cells extending parallel with the west side of the sealring, and situated between the west side of the sealring and the core region, wherein each of the horizontal I/O cells of the second linear array includes a fourth ESD protection cell stacked with a fourth diagonal signal routing cell in a west-to-east horizontal direction, respectively.

Aspect 20: The integrated circuit of aspect 19, wherein the first, second, third and fourth diagonal signal routing cells have substantially the same cell layout.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An integrated circuit, comprising:
a sealring;
a core region; and
a first input/output (I/O) cell, comprising:
a first diagonal signal routing cell; and
a first electrostatic discharge (ESD) protection cell stacked with the first diagonal signal routing cell between the sealring and the core region, wherein the first diagonal signal routing cell is configured to route a first outbound signal from a first pin located substantially at a first corner of the first diagonal signal routing cell adjacent to the core region to a second pin located substantially at a second corner of the first diagonal signal routing cell adjacent to the first ESD protection cell.

2. The integrated circuit of claim 1, wherein the first diagonal signal routing cell includes an output driver cell, wherein the second pin is located within the output driver cell.

3. The integrated circuit of claim 2, wherein the output driver cell is L-shaped including a corner coincident with the second corner of the first diagonal signal routing cell.

4. The integrated circuit of claim 2, wherein the first diagonal signal routing cell includes a set of one or more cells separating the output driver cell and the first ESD protection cell from the core region.

5. The integrated circuit of claim 1, wherein the first diagonal signal routing cell includes an L-shaped cell including a corner coincident with the first corner of the first diagonal signal routing cell.

6. The integrated circuit of claim 1, wherein the first diagonal signal routing cell includes a level shifter cell, a pre-driver cell, and an output driver cell, wherein the first outbound signal is routed from the first pin to the second pin via the level shifter cell, the pre-driver cell, and the output driver cell.

7. The integrated circuit of claim 1, wherein:
the first pin is a selected one of a first pair of selectable pins, the selected first pin situated closer to the core region than an unselected one of the first pair of selectable pins; and
the second pin is a selected one of a second pair of selectable pins, the selected second pin situated closer to the first ESD protection cell than an unselected one of the second pair of selectable pins.

8. The integrated circuit of claim 1, wherein the first pin is coupled to a first core circuit within the core region, and the second pin is coupled to the first ESD protection cell.

9. The integrated circuit of claim 8, wherein the first diagonal signal routing cell is configured to route an inbound signal from the second pin to a third pin coupled to a second core circuit within the core region.

10. The integrated circuit of claim 9, wherein the first diagonal signal routing cell includes a second ESD protection cell and a receiver cell, wherein the inbound signal is routed to the third pin via the second ESD protection cell and the receiver cell.

11. The integrated circuit of claim 1, wherein the first ESD protection cell is stacked with the first diagonal signal routing cell in a vertical direction between a north side or a south side of the sealring and the core region.

12. The integrated circuit of claim 11, further comprising a second I/O cell, comprising:
a second diagonal signal routing cell; and
a second ESD protection cell stacked with the second diagonal signal routing cell in a horizontal direction between an east side or a west side of the sealring and the core region, wherein the second diagonal signal routing cell is configured to route a second outbound signal from a first pin located substantially at a first corner of the second diagonal signal routing cell adjacent to the core region to a second pin located substantially at a second corner of the second diagonal signal routing cell adjacent to the second ESD protection cell.

13. The integrated circuit of claim 12, wherein the second diagonal signal routing cell has substantially the same cell layout as the first diagonal signal routing cell.

14. The integrated circuit of claim 13, wherein:
the first diagonal signal routing cell includes a first and a second selectable pins, the first pin of the first diagonal signal routing cell being the first selectable pin; and
the second diagonal signal routing cell includes a third and a fourth selectable pins located in the same layout location as the first and second selectable pins of the first diagonal signal routing cell, respectively, the first pin of the second diagonal signal routing cell being the fourth selectable pin.

15. The integrated circuit of claim 13, wherein:
the first diagonal signal routing cell includes a first and a second selectable pins, the second pin of the first diagonal signal routing cell being the first selectable pin; and
the second diagonal signal routing cell includes a third and a fourth selectable pins located in the same layout location as the first and second selectable pins of the first diagonal signal routing cell, respectively, the second pin of the second diagonal signal routing cell being the fourth selectable pin.

16. The integrated circuit of claim 13, further comprising:
a first set of metal traces extending parallel in the vertical direction, wherein the first set of metal traces overlie the first I/O cell;
a first shield situated between the first set of metal traces and the first I/O cell;
a second set of metal traces extending parallel along the horizontal direction, wherein the second set of metal traces overlie the second I/O cell; and
a second shield situated between the second set of metal traces and the second I/O cell, wherein a layout of the first shield is substantially the same as a layout of the second shield.

17. The integrated circuit of claim 1, wherein the first diagonal signal routing cell includes a first pre-driver cell and a second pre-driver cell, wherein the second pin is located within the second pre-driver cell.

18. The integrated circuit of claim 17, wherein the first I/O cell further includes an output driver cell, wherein the second pin is coupled to the first ESD protection cell via the output driver cell.

19. An integrated circuit, comprising:
a square or rectangular shaped sealring including a north side, an east side, a south side, and a west side;
a core region situated within the sealring;
a first linear array of vertical input/output (I/O) cells extending parallel with the north side of the sealring, and situated between the north side of the sealring and the core region, wherein each of the vertical I/O cells of the first linear array includes a first electrostatic discharge (ESD) protection cell stacked with a first diagonal signal routing cell in a north-to-south vertical direction, respectively;
a second linear array of vertical I/O cells extending parallel with the south side of the sealring, and situated between the south side of the sealring and the core region, wherein each of the vertical I/O cells of the second linear array includes a second ESD protection cell stacked with a second diagonal signal routing cell in a south-to-north vertical direction, respectively;
a first linear array of horizontal I/O cells extending parallel with the east side of the sealring, and situated between the east side of the sealring and the core region, wherein each of the horizontal I/O cells of the first linear array includes a third ESD protection cell stacked with a third diagonal signal routing cell in an east-to-west horizontal direction, respectively; and
a second linear array of horizontal I/O cells extending parallel with the west side of the sealring, and situated between the west side of the sealring and the core region, wherein each of the horizontal I/O cells of the second linear array includes a fourth ESD protection cell stacked with a fourth diagonal signal routing cell in a west-to-east horizontal direction, respectively.

20. The integrated circuit of claim 19, wherein the first, second, third and fourth diagonal signal routing cells have substantially the same cell layout.
